(19) United States
(12) Patent Application Publication
(10) Pub. No.: US 2025/0162884 A1
(43) Pub. Date: May 22, 2025

(54) Self-Replicating Nano Factory and Uses Thereof

(71) Applicant: West Nanorobotics LLC, Pendleton, IN (US)

(72) Inventor: Tory C Weston, Pendleton, IN (US)

(73) Assignee: West Nanorobotics LLC, Pendleton, IN (US)

(21) Appl. No.: 18/517,374

(22) Filed: Nov. 22, 2023

(51) Int. Cl. C01B 33/12; C01B 32/16; C01B 32/956; H01J 37/317

(52) U.S. Cl. CPC C01B 33/126; C01B 32/16; C01B 32/956; H01J 37/3174

(57) ABSTRACT

This is a self-replicating nanofactory which uses nano-electron lithography to assemble copies of itself along with nanoscale precise products. The device is 100 nm×100 nm×100 nm in size making it a type of nanomachine that assembles products being a nanofactory. The device is composed of carbon nanotubes, silicon carbide and silica which are naturally available in the form of carbon dioxide and silicon dioxide on many planets and asteroids in the universe. This device uses sugar to power itself as the carbon based nanomachines being cells and bacteria use as a power source which can be naturally sourced in a environment as well.

| Name | City | State | Country |
|---|---|---|---|
| West | Pendleton | IN | US |
| Nanorobotics | | | |
| LLC | | | |

| | |
|---|---|
| Assignee: | West Nanorobotics LLC |
| Appl. No.: | 63/474,335 |
| Filed: | Aug. 9, 2022 |

### BRIEF SUMMARY

These self-replicating nanofactory devices are used for industrial applications such as manufacturing which are self-replicating. They can produce nanoscale precise products of any kind made of Carbon nanotubes, Silicon Carbide, and Silica using sugar, carbon dioxide, and silicon dioxide as a source of materials. These self-replicating nanofactories have several components that allow the functionality of the self-replicating nanofactory. The devices have built in nanoscale wifi chips as a components thus are able to receive instructions from a computer such as a laptop or desktop with a wifi card. The self-replicating nanofactories also have a built in computer which includes the components of any computer however on a scale smaller than 100 nm×100 nm×100 nm such as Random Access Memory, Central Processing Unit, Wifi Chip, Solid State Drive, and Cooling Units. The self-replicating nanofactory includes components for power as well such as a synthetic mitochondria and EMF Inductors to generate mechanical force and DC current. The Self-replicating nanofactory has a storage system to contain large quantities of aqueous sugar to power itself. The Self-replicating nanofactory includes a component being the nanoscale electron beam lithography device which allows for manufacturing and self-replication. The Self-replicating nanofactory includes components such as propellers to achieve flight much in the same way a helicopter or drone works being powered by the synthetic mitochondria.

The electronic components use the Carbon Nanotubes as wires and the Silicon Carbide as a semiconductor. The silica is used as material to make the non-electronic components being used as a type of building material. These Self-replicating nanofactories being a type of Utility Fog used for aerial applications such as manufacturing of nanoscale precise products and copies of itself.

### BRIEF DESCRIPTION OF THE FIGURES

FIG. 1, Silicon Self-Replicating Nanofactory Diagram

FIG. 2, Nanoscale Electron Beam Lithography Molecular Assembler Diagram

FIG. 3, Carbon Dioxide Nano-Filter Diagram

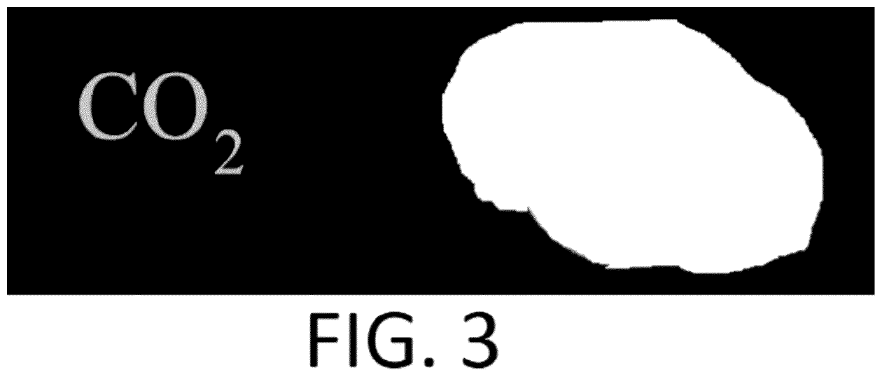

FIG. 4, Silicon Dioxide Nano-Filter Diagram

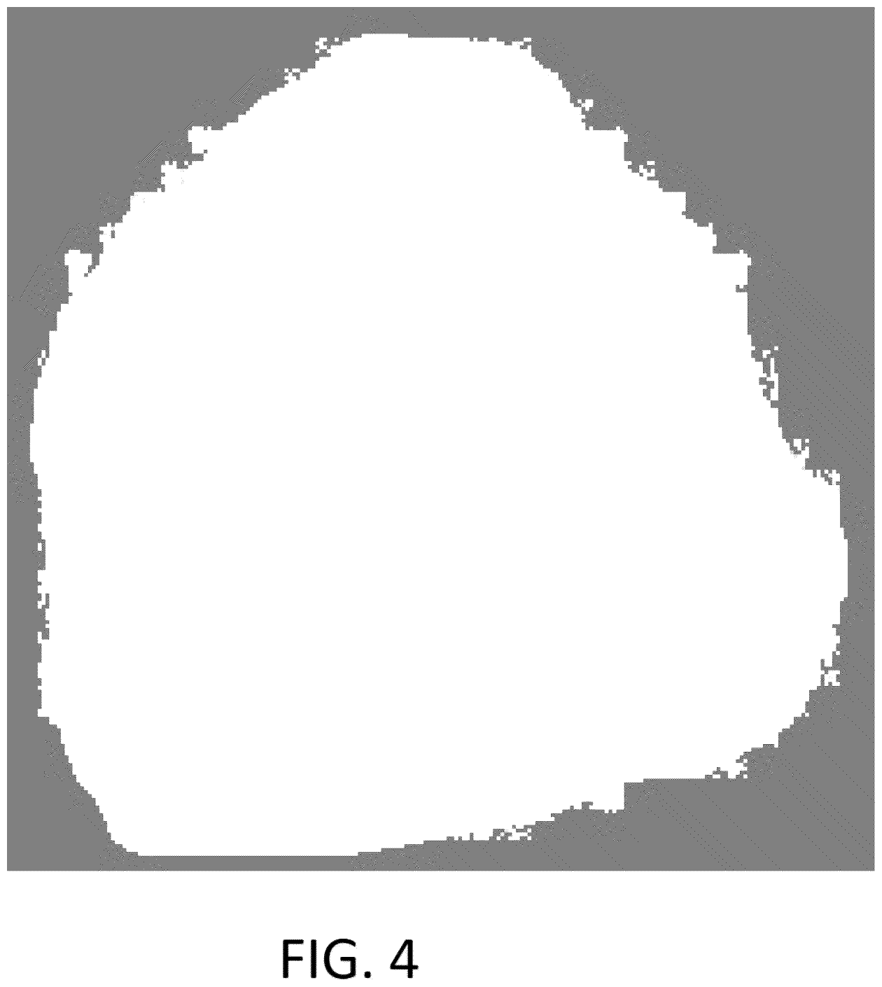

FIG. 5, Nanoscale Motor which is apart of the Synthetic Mitochondria Diagram

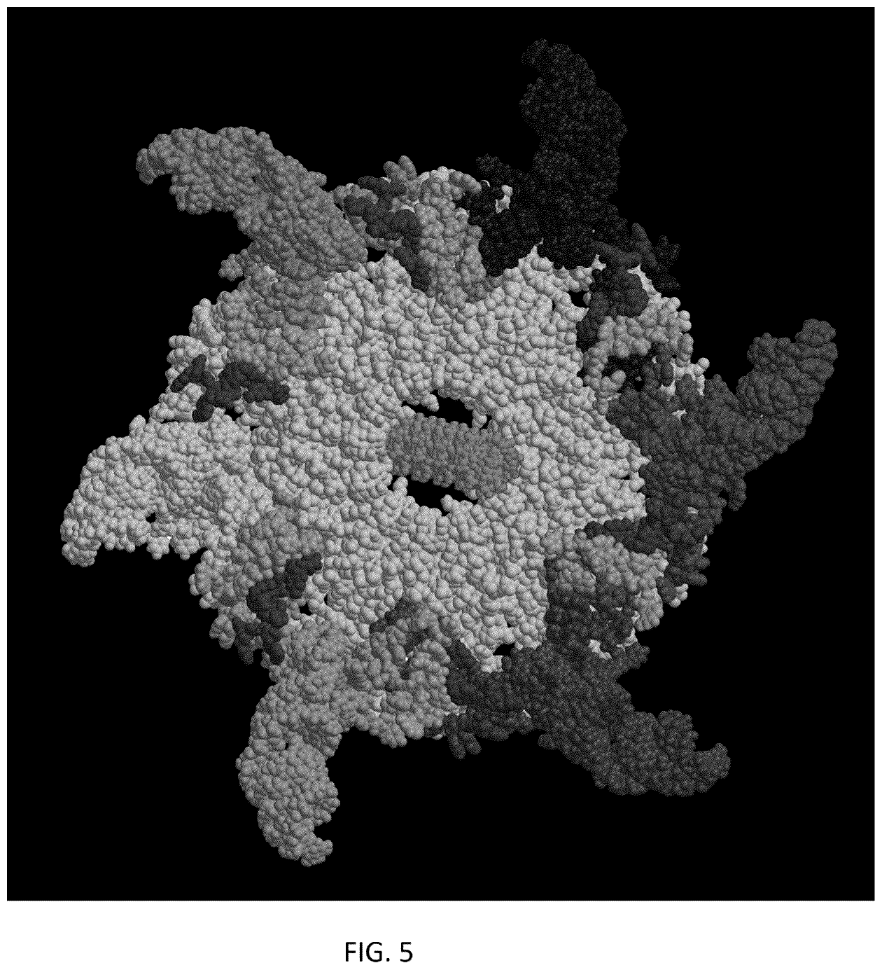

FIG. 6, Nanoscale Wifi Chip Diagram

### DETAILED DESCRIPTION

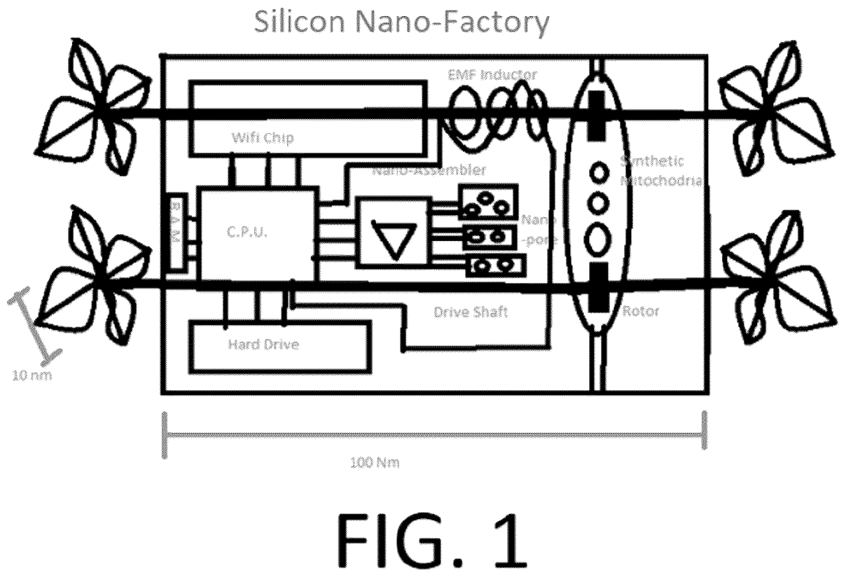

There are many parts that are nanoscale to the self-replicating nanofactories such as Random Access Memory, Central Processing Unit, Wifi Chip, Solid State Drive, Cooling Units, Synthetic Mitochondria, EMF Inductors, Storage System, Electron Beam Lithography Molecular Assembler, Nano-Filters, and Propellers each of which will be explained in the following order. These parts make the entire self-replicating nanofactory when combined according to FIG. 1.

First, the Random Access Memory which is constructed in the same fashion as standard computer R.A.M., however is constructed of Carbon Nanotube circuits with Silicon Carbide being used as the semiconductor. The process for construction is electron beam lithography by the Electron Beam Lithography Molecular Assembler as with all the components of the self-replicating nanofactory. The R.A.M.'s storage is 64 bytes being constructed of thousands small 1 nm capacitors and transistors. They will need to be constructed three dimensionally taking up 19 nm×19 nm×19 nm of volume being the active memory of the device.

Second, The Central Processing Unit which is constructed in the same fashion as standard computer C.P.U.s however is constructed of Carbon Nanotube circuits with Silicon Carbide used as the semiconductor. The processor will be a 8 bit processor with 3,500 transistors that are all 1 nm in size and 16 byte front side bus which will take up 17×17×17 nm. This processing chip is for the most part like a Intel 8008 chip but constructed at a much smaller scale which will be running at 500 kilohertz as the frequency of the C.P.U. For this device.

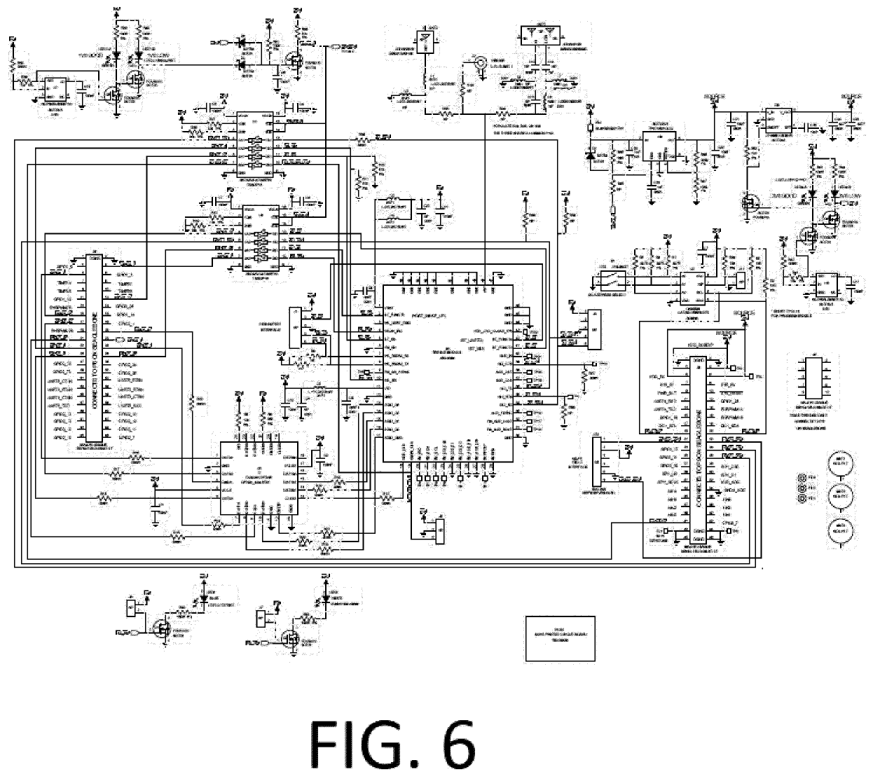

Third, The Wifi Chip which is constructed of Carbon Nanotube and Silicon Carbide components which follows the exact pattern as shown in FIG. 6 which is small being 5 nm×5 nm×5 nm constructed three dimensionally within the self-replicating nanofactory. This part of the self-replicating nanofactory allow for communication with external computers which control the actual nanofactory's movements programming the self-replicating nanofactory.

Fourth, The solid state drive is constructed of the same materials as the Random Access Memory of the self-replicating nanofactory however the only difference is this is a 128 byte solid state drive having tens of thousands of transistors and capacitors taking up a total of 23 nm×23 nm×23 nm in volume which is constructed three dimensionally just as the Random Access Memory of the self-replicating nanofactory being made of 1 nm components.

Fifth, The cooling system which is a series of three small 2 nm×2 nm×100 nm pipes that run near the electronic components of the self-replicating nanofactory with a series of 1 nm×1 nm×1 nm fans in them removing heat from the electronic components of the self-replicating nanofactory. These fans will move either liquid or air molecules through the pipes depending on what medium the self-replicating nanofactory is in.

Sixth, The Synthetic Mitochondria is constructed of silica and silicon carbide being a set of chambers that combustion of sugar happens in being 10 nm×30 nm×10 nm allowing for 0.00477 nanograms of sugars to be contained within the synthetic mitochondria making 67.84 nanojoules of energy when the entire reaction chamber is combusted powering the self-replicating nanofactory's various functions. The combustion in water generates steam as the small amounts of water in the synthetic mitochondria turn a nanomotor that leads to a driveshaft that creates mechanical motion.

Seventh, The EMF inductor is wrapped around the driveshaft leading from the synthetic mitochondria which the EMF inductor is constructed of Carbon Nanotube wires allowing for current to be generated from the mechanical motion caused from the synthetic mitochondria's combustion of sugar. This allows for a DC current to be created powering the electronic components such as the C.P.U., Wifi Chip, R.A.M., Solid State Drive, and Electron Beam Lithography Molecular Assembler.

Eighth, The storage system which is a set of cubes that store carbon dioxide, sugar, and silica. The chambers of the storage system is 30×10×10 nm split into three compartments for each of the various materials. This acts as a fuel tank for the self-replicating nanofactory being connected to the synthetic mitochondria and electron beam molecular assembler based on the input being stored within the compartment which have a external opening with nano-filters.

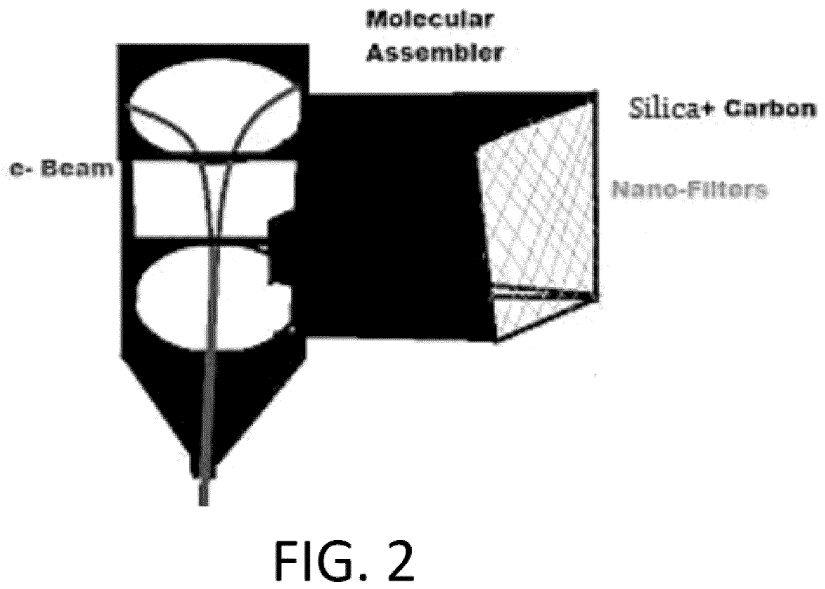

Ninth, Electron Beam Lithography Molecular Assembler which is constructed of Silicon Carbide, Carbon Nanotubes, and Silica being a set of chambers as in FIG. 2 that condense a beam of electrons into a small 1 nm radius sized location which allow for the construction of all the components of the self-replicating nanofactory. This device will create covalent bonds between Carbon to Carbon, Silicon to Carbon, or Oxygen to Oxygen by putting a electron in orbit of the two atoms by precise movements of the self-replicating nanofactory being able to form bonds on the atomic scale between atoms building the self-replicating nanofactories atom by atom. The Silica and Carbon dioxide enter the end electron beam lithography molecular assembler to be hit by the electron beam and ionized then bonded in a set of several configurations making Silicon Carbide, Carbon Nanotubes, or Silica sols by creating covalent bonds which allows for the creation of any object to the precision of 1 nm or larger. The size of this device which extends from the underside of the self-replicating nanofactory is 30 nm×30 nm×50 nm.

Tenth, The nanofilters are nanopores that allow for the passage of one type of material into the storage chamber which is sugar, carbon dioxide, silica, or water. There are a total for four types of nano-filter which are cut to only allow a single atom of the molecules through the filter of one type which there is a series of these that open to the outside of the device for each type of molecule to enter the device that is needed for the building operations or to fuel the device.

Eleventh, The propellers which are attached to the driveshaft there are a total of four propellers two on each side of the device which allow for flight much like a helicopter or drone. These propellers receive mechanical motions from the nanomotor of the synthetic mitochondria.

The original self-replicating nanofactory is constructed by a macroscale electron beam lithography device with a resolution small enough to make covalent bonds and ionize atoms which is a higher resolution than 1 nm.

### How to Use

To use these device you find a location that has the required materials such as Silica, Carbon Dioxide, Sugar, and Water then place these devices near it. They will use the materials to construct any object made of Silicon Carbide, Carbon Nanotubes, or Silica to atomic precision in the environment using available materials being controlled by a external computer being a programming transponder for the self-replicating nanofactories by wireless communications via Wifi.

1. Any Self-Replicating Nanofactory especially those that are composed of Carbon Nanotubes, Silicon Carbide, and Silica.

2. Any Nanomachine that uses a nanoscale electron beam molecular assembler to produce copies of itself.

3. Any Nanomachine that uses a nanoscale electron beam molecular assembler to produce nanoscale precise products of any sort especially those that are constructed of Carbon Nanotubes, Silicon Carbide, or Silica.

4. The Method of claims 2 and 3 being the technology that makes this possible which is the nanoscale electron beam molecular assembler and its components such as molecular nano-filters.

5. Any component of the self-replicating nanofactory that are listed in this patent document that have been changed to be smaller than 100 nm×100 nm×100 nm in total size, such as the synthetic mitochondria as a example, however this includes all of them listed in any part of the document.
